(19) United States
(12) Patent Application Publication
(10) Pub. No.: US 2020/0365482 A1
(43) Pub. Date: Nov. 19, 2020

(54) ELECTRONIC MODULE FOR POWER CONTROL

(71) Applicant: ZF Friedrichshafen AG, Friedrichshafen (DE)

(72) Inventors: Thomas Maier, Neunburg v. Wald (DE); Hermann Josef Robin, Regensburg (AT)

(73) Assignee: ZF Friedrichshafen AG, Friedrichshafen (DE)

(21) Appl. No.: 16/875,162

(22) Filed: May 15, 2020

(30) Foreign Application Priority Data
May 15, 2019 (DE) 102019207012.4

(51) Int. Cl. H01L 23/367; H01L 25/07; H01L 23/50

(52) U.S. Cl. CPC H01L 23/3672; H01L 23/50; H01L 25/072

(57) ABSTRACT

An electronic module for power control includes a carrier element, at least one power switching element having a cooling surface, and a cooling body. The at least one power switching element may be electrically connected to the carrier element. In an assembled state of the electronic module, the cooling body may be thermally conductively connected directly to the cooling surface of the power switching element. When a busbar is present, the busbar may be arranged between the carrier element and the at least one power switching element thereby producing an electrical connection between the carrier element and the at least one power switching element.

### CROSS-REFERENCE TO RELATED APPLICATION

This application claims priority to German Patent Application No. 102019207012.4 filed on May 15, 2019, the disclosure of which is incorporated herein by reference in its entirety.

### TECHNICAL FIELD

The present disclosure relates to an electronic module for power control.

### BACKGROUND

A major challenge in the production of electronic modules, for instance for transmission control or power control in vehicles, is posed by the increasing miniaturization of electronic components. In this case, the desire to integrate ever more power into a structural space becoming ever smaller necessitates correspondingly stringent requirements in respect of heat dissipation.

The German patent application DE 10 2018 205 243.3, not previously published, discloses an electronic module for power control. The electronic module comprises a carrier element with at least one power switching element, a cooling body for cooling the power switching element, and a housing.

### SUMMARY

The present disclosure specifies an electronic module which, with respect to the prior art, is constructed more compactly and is suitable for higher power currents.

The electronic module according to the present disclosure comprises a carrier element, at least one power switching element having a cooling surface, said at least one power switching element being electrically connected to the carrier element, and a cooling body. In an assembled state of the electronic module, the cooling body is thermally conductively connected directly to the cooling surface of the power switching element. Furthermore, a busbar is present, which is arranged between the carrier element and the at least one power switching element and produces an electrical connection between the carrier element and the at least one power switching element.

The electronic module according to the invention thus provides a module having a high integration density and optimum thermal linking of the at least one power switching element to the cooling body. At the same time, the use of a busbar ensures that high currents can be transported to the power switching elements. The approach described here is based on the insight that more efficient heat dissipation by comparison with known technical solutions can take place as a result of the direct coupling of the cooling surface of the power switching element to the cooling body. The use of a busbar makes it possible to adapt the dimensions of the busbar independently of the dimensions of the conductor tracks within the carrier element. This allows a higher flexibility in the construction of an electronic module for different currents.

An electronic module can be understood to mean, for example, a module for controlling a transmission, in particular, a vehicle transmission, or a power electronic module. A carrier element can be understood to mean, for example, a printed circuit board, also called circuit board or PCB. The carrier element can be populated with electronic components on one or two sides, depending on the embodiment. A power switching element can be understood to mean an electronic switch, for instance a MOSFET or some other semiconductor-based power switch. In particular, the power switching element can involve output stages of an amplifier circuit. In this case, a plurality of power switching elements can be connected in parallel with one another. The cooling surface can be, for example, in each case a surface section of a top side of the power switching element facing away from the carrier element. A cooling body can be understood to mean a body composed of a material having a comparatively high thermal conductivity, in particular, a body composed of copper or composed of some other suitable metal. The cooling body can for example also be realized as a composite composed of different materials. A cooling body can furthermore be understood to mean a body which functions as a heat sink and which can absorb heat and release it again particularly well by virtue of its geometry or its material constitution.

The power switching element can be realized as a MOSFET, an IGBT or a thyristor.

The busbar can be a part of the carrier element. This means that the busbar is already integrated into the carrier element in the process for producing the latter. As a result, it is possible that conduction paths between the busbar and e.g. electronic components integrated in the carrier element can be minimized. Furthermore, it is possible to integrate the busbar optimally into the carrier element since the course of other conductor tracks can be taken better into consideration. However, it is also possible that the busbar can be applied to the carrier element and can be electrically connected thereto. In this case, the production of an electrical connection between the busbar and the carrier element can be affected by means of an SMD process, press-fit, sintering, soldering, adhesive bonding or welding. In this case, an electrical connection can be produced between the busbar and a conductor track integrated in the carrier element. Said conductor track integrated in the carrier element can e.g. likewise be a busbar.

The power switching element can be applied to the busbar cohesively. In this case, the production of the connection can be affected e.g. by means of soldering, sintering, adhesive bonding, welding or other methods familiar to a person skilled in the art.

The electronic module can comprise a housing, which encloses the at least one power switching element and the busbar completely in an oil-tight fashion. As a result, when the electronic module is used in an oil chamber, e.g. in a transmission, oil and/or metallic abraded parts situated there is/are prevented from reaching the busbar and/or the power switching element. Corrosion damage and short circuits in the power switching element can be prevented as a result. Furthermore, the carrier element and the cooling body can be enclosed by the housing at least partly in an oil-tight fashion. It is possible for those regions of the carrier element and/or cooling body which constitute e.g. a transition to another component or which have e.g, sensitive metallic structures, e.g. conductor tracks on the carrier element, to be closed off in an oil-tight fashion. Furthermore, the structural space present can be optimally utilized by means of partial enclosure of the carrier element and of the cooling body.

In this case, the housing can be formed from a housing material. A housing material can be understood to mean, for instance, a plastic or a plastic-containing composite material, e.g. a moulding compound. The housing can be produced particularly cost-effectively and compactly as a result. In this case, it is possible for the busbar, the at least one power switching element and the carrier element and the cooling body to be encapsulated or partly encapsulated with the moulding compound by injection moulding. As a result, it is possible that the electronic module can also be installed in the oil chamber of a transmission of a motor vehicle.

The cooling body of the electronic module, on a side facing away from the cooling surface of the power switching element, can have a cooling structure for linking a further cooler. Said cooling structure can be e.g. a meandering channel or a PinFin structure for passing a cooling medium through it. The further cooler can be e.g. a cooling body of some other electronic module. However, it is also possible for the further cooler to be some other heat sink e.g. of a vehicle. In this case, the cooling body of the electronic module can have a seal that can seal the connection between the cooling body and the further cooler. What is achieved by means of this sealing is that, in the assembled state, no cooling medium can escape from the cooling structure.

The cooling body can at least for the most part be realized from copper and/or comprise copper as main constituent. By way of example, the cooling body can be realized as a copper plate or a copper sheet. Alternatively, the cooling body can be realized from a copper-containing alloy. Efficient heat dissipation in conjunction with comparatively low production costs is made possible as a result.

The cooling body can have perforations extending from a contact region of the power switching element on the busbar right into a region outside the electronic module. Said perforations, e.g. holes, make it possible to secure a contact pin of the power switching element on the busbar by means of laser welding, for example. The perforation can be covered by the housing in the assembled state. Furthermore, it is possible for the perforation to be filled with the moulding compound.

The electronic module can be used in a motor vehicle for controlling an electric motor in the drivetrain or in a steering system. The electronic module as a power module can switch voltages in the range of 400 V to 1000 V. Furthermore, it is possible that, besides one or more power switching elements, link circuit capacitors are also installed in the electronic module.

The invention is explained in greater detail by way of example with reference to the accompanying drawing. The sole FIGURE shows a schematic cross-sectional illustration of an electronic module in accordance with one exemplary embodiment of the present invention.

### BRIEF DESCRIPTION OF THE DRAWINGS

FIG. 1 shows electronic module for power control according to an embodiment of the present disclosure.

### DETAILED DESCRIPTION

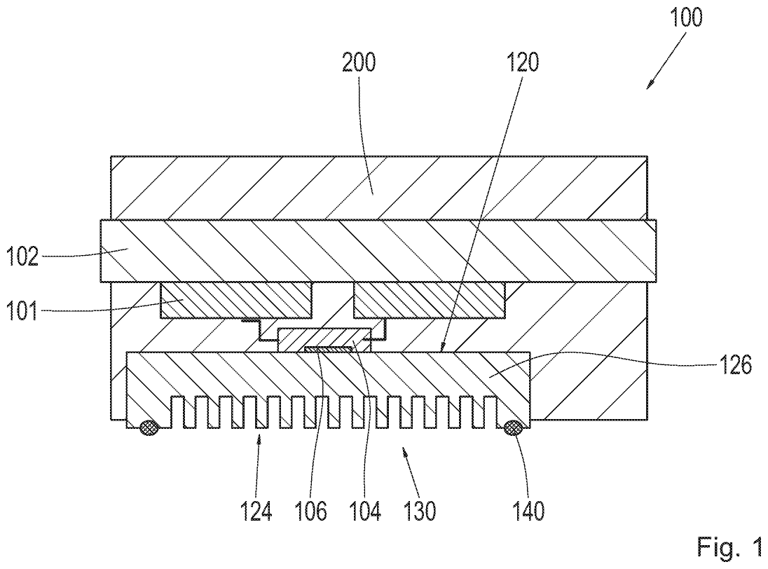

FIG. 1. shows a schematic cross-sectional illustration of an electronic module 100 for power control in accordance with one exemplary embodiment of the present disclosure. The electronic module 100, for example a component of an electronic control unit or of power electronics for an (electric) vehicle, comprises a carrier element 102, also called circuit carrier, which on one side is populated with one or more busbars 101 and also with a first power switching element 104 having a first cooling surface 106. The cooling surface 106 serves for dissipating heat via a top side of the power switching element 104 facing away from the carrier element 102, which is also referred to as top side cooling. The power switching element 104 is realized as MOSFET output stages, for example.

In the exemplary embodiment illustrated, the busbars 101 are applied on a top side of the carrier element 102. In this case, the busbars 101 are fixedly connected to the carrier element 102, such that the busbars 101 are prevented from slipping or detaching from the carrier element 102. Moreover, the busbars 101 are connected to electrical conductor tracks (not illustrated) that are optionally present in the carrier element 102.

The power switching element 104 is applied on the busbars 101 in such a way that an electrical connection between the connecting pins of the power switching element 104 and the busbars 101 is as free of losses as possible. In this case, the securing is affected by means of soldering, welding or other connection techniques for producing an electrical connection that are familiar to a person skilled in the art.

By way of example, the cooling surface 106 is thermally conductively connected to a cooling body 126 in each case by soldering at a soldering point. Alternatively, the cooling surface 106 is cohesively connected to the cooling body 126 by adhesive bonding. By way of example, a plurality of power switching elements 104 can be present, which are likewise thermally conductively connected by their cooling surfaces 106 to a contacting side 120 of the cooling body 126. Consequently, the cooling surfaces 106 of the plurality of power switching elements 104 are thermally coupled to one another via the cooling body 126. By virtue of the fact that the cooling body 126 also extends over regions of the carrier element 102 that lie between the plurality of power switching elements 104, the heat dissipation via the cooling body 126 can be effected particularly efficiently since a total surface area of the cooling body 126 turns out to be significantly larger in comparison with a total surface area of the cooling surfaces 106 of the plurality of power switching elements 104 or a total surface area of cooling laminae applied separately to respectively one of the power switching elements 104.

A second contacting side 124 of the cooling body 126, situated opposite the contacting side 120, serves for forming a cooling structure 130, e.g. a meandering channel or a PinFin structure for thermally conductive contacting to a further cooling body (not illustrated). A seal 140 is formed on the second contacting side 124 of the cooling body 126. Said seal serves to ensure that, in the assembled state of the electronic module 100 on a further cooling body, the cooling medium flowing through the cooling structure cannot escape. The inlet and outlet of the cooling medium into and out of the cooling structure are moreover not illustrated. The cooling body 126 is embodied for example as a component of a water cooler.

The housing 200 is formed for example by the electronic module 101 being encapsulated by injection moulding with a suitable housing material, for example a thermosetting plastic or some other suitable plastic or plastic-containing composite material.

If an exemplary embodiment includes an “and/or” linkage between a first feature and a second feature, then this can be interpreted such that the exemplary embodiment has both the first feature and the second feature in accordance with one embodiment and either only the first feature or only the second feature in accordance with a further embodiment.

While example, non-limiting embodiment has been presented in the foregoing detailed description, it should be appreciated that a vast number of variations exist. It should also be appreciated that the exemplary embodiment is only an example, and is not intended to limit the scope, applicability, or configuration of the disclosure in any way. Rather, the foregoing detailed description will provide those skilled in the art with a convenient road map for implementing the exemplary embodiment. It should be understood that various changes can be made in the function and arrangement of elements without departing from the scope of the disclosure as set forth in the appended claims and the legal equivalents thereof.

What is claimed is:

1. An electronic module for power control comprising:
a carrier element,
at least one power switching element having a cooling surface, with the at least one power switching element being electrically connected to the carrier element, and
a cooling body that is thermally conductively connected directly to the cooling surface of the power switching element, and
a busbar arranged between the carrier element and the at least one power switching element producing an electrical connection between the carrier element and the at least one power switching element.

2. The electronic module of claim 1, wherein the busbar is a part of the carrier element.

3. The electronic module of claim 1, wherein the busbar is applied to the carrier element and is electrically connected to the carrier element.

4. The electronic module of claim 1, further comprising a housing, which encloses the at least one power switching element and the busbar and the carrier element and the cooling body at least partly in an oil-tight fashion.

5. The electronic module of claim 4, wherein the housing is formed from a moulding compound.

6. The electronic module of claim 1, wherein the cooling body, on a side facing away from the cooling surface, has a cooling structure for linking to a further cooler.

7. The electronic module of claim 1, wherein the cooling body is at least partially realized from copper or a copper alloy.

8. The electronic module of claim 1, wherein the cooling body is cohesively connected to the cooling surface.

9. The electronic module of claim 1, where in the cooling body is soldered and/or adhesively bonded to the cooling surface.

10. The electronic module of claim 2, further comprising a housing, which encloses the at least one power switching element and the busbar and the carrier element and the cooling body at least partly in an oil-tight fashion.

11. The electronic module of claim 2, wherein the cooling body, on a side facing away from the cooling surface, has a cooling structure for linking to a further cooler.

12. The electronic module of claim 2, wherein the cooling body is cohesively connected to the cooling surface.

13. An electronic module for power control comprising:
a carrier element,
at least one power switching element having a cooling surface, with the at least one power switching element being electrically connected to the carrier element, and
a cooling body that is thermally conductively and cohesively connected directly to the cooling surface of the power switching element and on a side facing away from the cooling surface, has a cooling structure for linking to a further cooler,
a busbar arranged between the carrier element and the at least one power switching element producing an electrical connection between the carrier element and the at least one power switching element, and
a housing, which encloses the at least one power switching element and the busbar and the carrier element and the cooling body at least partly in an oil-tight fashion.
